(19) United States
(12) Patent Application Publication
(10) Pub. No.: US 2025/0344460 A1
(43) Pub. Date: Nov. 6, 2025

(54) LDMOS HAVING MULTIPLE FIELD PLATES AND ASSOCIATED MANUFACTURING METHOD

(71) Applicant: Chengdu Monolithic Power Systems Co., Ltd., Chengdu (CN)

(72) Inventors: Yanjie Lian, Chengdu (CN); Daping Fu, Chengdu (CN)

(21) Appl. No.: 19/271,026

(22) Filed: Jul. 16, 2025

Related U.S. Application Data
(63) Continuation-in-part of application No. 18/650,680, filed on Apr. 30, 2024.
Application No. 18/650,680 is a continuation of application No. 17/582,159, filed on Jan. 24, 2022, now Pat. No. 12,002,848.

(30) Foreign Application Priority Data
Feb. 8, 2021 (CN) 202110173502.4
May 19, 2025 (CN) 202510645197.2

(51) Int. Cl. H10D 62/10; H10D 30/01; H10D 30/65; H10D 64/00

(52) U.S. Cl. CPC H10D 62/103; H10D 30/0281; H10D 30/65; H10D 64/111

(57) ABSTRACT

A LDMOS including a semiconductor substrate, a gate oxide, a gate, field plate oxide layers and field plate barrier layers is disclosed. A first field plate oxide layer and a second field plate oxide layer are positioned atop the gate oxide with a spacing between them. A first field plate barrier layer and a second field plate barrier layer are positioned atop the first and the second field plate oxide layers, respectively. A third field plate barrier layer is positioned atop the first and the second field plate barrier layers and the spacing. A third field plate oxide layer is positioned atop the third field plate barrier layer. The third field plate oxide layer includes a first portion positioned atop the first field plate oxide layer and a second portion positioned atop the spacing. A fourth field plate barrier layer is positioned atop the third field plate oxide layer.

### CROSS-REFERENCE TO RELATED APPLICATIONS

The present application claims the benefit of CN patent application No. 202510645197.2, filed on May 19, 2025. The present application is also a continuation-in-part of U.S. patent application Ser. No. 18/650,680, filed on Apr. 30, 2024, which is a continuation to U.S. patent application Ser. No. 17/582,159, filed on Jan. 24, 2022, which claims the benefit of CN patent application No. 202110173502.4, filed on Feb. 8, 2021. All of these related applications are incorporated herein by reference in their entirety.

### TECHNICAL FIELD

This disclosure generally relates to a lateral double diffused metal oxide semiconductor field effect transistor (LDMOS), and more particularly but not exclusively relates to an LDMOS having multiple field plates.

### BACKGROUND

It is well known that a high voltage LDMOS usually has field plates to increase the breakdown voltage of the LDMOS, and changing thickness of an oxide layer under the field plates can affect electric field distribution. The field plates are distributed between the drain and the gate of the LDMOS, and it is usually desired to have the thickness of the oxide layer under the field plate increases sequentially from the gate to the drain. Usually additional masks are required for manufacturing the oxide layer with different thickness, thus the manufacturing cost of the LDMOS is increased.

Therefore, it is desired to manufacture an oxide layer under the field plates to have an optimized thickness without additional masks.

### SUMMARY

In accomplishing the above and other objects, the present disclosure provides an LDMOS including a semiconductor substrate, a gate oxide, a gate, a first field plate oxide layer, a second field plate oxide layer, a third field plate oxide layer, a first field plate barrier layer, a second field plate barrier layer, a third field plate barrier layer and a fourth field plate barrier layer. The semiconductor substrate has a source and a drain. The gate oxide is positioned atop the semiconductor substrate. The gate is positioned between the source and drain. The first field plate oxide layer and the second field plate oxide layer are positioned atop the gate oxide, and a spacing is between the first field plate oxide layer and the second field plate oxide layer. The first field plate barrier layer and the second field plate barrier layer are positioned atop the first field plate oxide layer and the second field plate oxide layer, respectively. The third field plate barrier layer is positioned atop the first field plate barrier layer, the second field plate barrier layer, and the spacing between the first field plate oxide layer and the second field plate oxide layer. The third field plate oxide layer is positioned atop the third field plate barrier layer, and the third field plate oxide layer includes a first portion positioned atop the first field plate oxide layer and a second portion positioned atop the spacing between the first field plate oxide layer and the second field plate oxide layer. The fourth field plate barrier layer is positioned atop the third field plate oxide layer.

In accomplishing the above and other objects, the present disclosure provides an LDMOS including a semiconductor substrate, a gate oxide, a gate, a first field plate oxide layer, a second field plate oxide layer, a third field plate oxide layer, a first field plate barrier layer, a second field plate barrier layer, a third field plate barrier layer and a fourth field plate barrier layer. The semiconductor substrate has a source and a drain. The gate oxide is positioned atop the semiconductor substrate. The gate is positioned between the source and drain, and includes a plate portion positioned atop the gate oxide. The first field plate oxide layer and the second field plate oxide layer are positioned atop the gate oxide, and a spacing is between the first field plate oxide layer and the second field plate oxide layer. The first field plate barrier layer and the second field plate barrier layer are positioned atop the first field plate oxide layer and the second field plate oxide layer, respectively. The third field plate barrier layer is positioned atop the first field plate barrier layer, the second field plate barrier layer, and the spacing between the first field plate oxide layer and the second field plate oxide layer. The third field plate oxide layer is positioned atop the third field plate barrier layer, and the third field plate oxide layer includes a first portion positioned atop the first field plate oxide layer and a second portion positioned atop the spacing between the first field plate oxide layer and the second field plate oxide layer. The fourth field plate barrier layer is positioned atop the third field plate oxide layer.

In accomplishing the above and other objects, the present disclosure provides an LDMOS including a semiconductor substrate, an interlayer dielectric layer, a gate conducting layer, a low side field plate barrier layer and a high side field plate barrier layer. The semiconductor substrate has a source and a drain. The interlayer dielectric layer is positioned atop the semiconductor substrate. The gate conducting layer is positioned atop the semiconductor substrate between the source and the drain. The gate conducting layer includes a plate portion and a channel portion, and a height of the plate portion to a upper surface of the semiconductor substrate is greater than a height of the channel portion to the upper surface of the semiconductor substrate. The low side field plate barrier layer is positioned in the interlayer dielectric layer and includes a first portion, a second portion and a third portion. The first portion is positioned in the interlayer dielectric layer close to the drain, the second portion is positioned in the interlayer dielectric layer close to the source, and the third portion is positioned between the first portion and the second portion. The high side field plate barrier layer is positioned in the interlayer dielectric layer atop the first portion and the third portion of the low side field plate barrier layer.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a cross-sectional view of an LDMOS 100 according to an embodiment of the present invention.

FIG. 2 illustrates a cross-sectional view of an LDMOS 200 according to an embodiment of the present invention.

FIG. 3 illustrates a flow chart of a method 300 for manufacturing an LDMOS according to an embodiment of the present invention.

FIGS. 4A-4K illustrate a cross-sectional view of an LDMOS in some steps of the method 300 according to an embodiment of the present invention.

FIG. 5 illustrates a cross-sectional view of an LDMOS 500 according to an embodiment of the present invention.

FIG. 6 illustrates a cross-sectional view of an LDMOS 600 according to another embodiment of the present invention.

FIG. 7 illustrates a cross-sectional view of an LDMOS 700 according to an embodiment of the present invention.

FIG. 8 illustrates a cross-sectional view of an LDMOS 800 according to an embodiment of the present invention.

### DETAILED DESCRIPTION

Various embodiments of the present invention will now be described. In the following description, some specific details, such as example circuits and example values for these circuit components, are included to provide a thorough understanding of the embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled,” as used herein, is defined as directly or indirectly connected in an electrical or non-electrical manner. The terms “a,” “an,” and “the” include plural reference, and the term “in” includes “in” and “on”. The phrase “in an embodiment,” as used herein does not necessarily refer to the same embodiment, although it may. The term “or” is an inclusive “or” operator, and is equivalent to the term “and/or” herein, unless the context clearly dictates otherwise. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. Those skilled in the art should understand that the meanings of the terms identified above do not necessarily limit the terms, but merely provide illustrative examples for the terms.

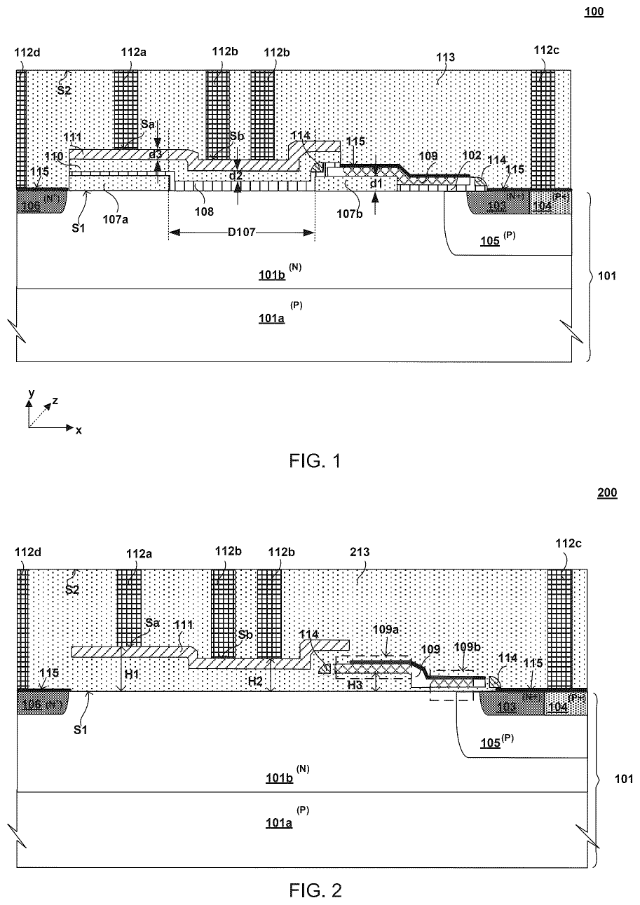

FIG. 1 illustrates a cross-sectional view of an LDMOS 100 according to an embodiment of the present invention. The cross-sectional view is shown in a three-dimensional coordinate system defined by the mutually perpendicular x-axis, y-axis, and z-axis and the cross-sectional view is cutting the LDMOS 100 from a plane defined by the x and y axis. Throughout this disclosure, lateral refers to a direction parallel to the x axis while vertical refers to a direction parallel to the y axis. The LDMOS 100 may comprise a semiconductor substrate 101, a source 103 and a drain 106. The semiconductor substrate 101 comprises an initial substrate 101a having a first conductivity type (the first conductivity type is P-type in the embodiment shown in FIG. 1), and a drift region 101b having a second conductivity type (the second conductivity type is N-type). The source 103 is the second conductivity type and is formed in the drift region 101b. The source 103 is separated from the drift region 101b by a body 105 having a first conductivity type. The source 103 has a heavier doping concentration than the drift region 101b (the doping type and concentration of the source 103 is denoted as N+ in FIG. 1). The LDMOS 100 may further comprise a body contact 104, the body contact 104 is disposed in the body 105 and has a heavier doping concentration than the body 105 (the doping type and concentration of the body 105 is denoted as P+ in FIG. 1). The drain 106 has a second conductive type and is formed in the drift region 101b. The drain 106 is separated from the source 103, and has a heavier doping concentration than the drift region 101b (the doping type and concentration of the drain 106 is denoted by N+ in FIG. 1).

Still referring to FIG. 1, as the embodiment shown in FIG. 1, the LDMOS 100 further comprises a first gate oxide 107a, a second gate oxide 107b, a gate having a source side and a drain side, a field plate oxide layer 110, and a field plate barrier layer 111. The body 105 is formed in the semiconductor substrate 101 on the source side of the gate, while the drain 106 is formed in the semiconductor substrate 101 on the drain side of the gate. Both the first gate oxide 107a and the second gate oxide 107b are located above semiconductor substrate 101 between the drain 106 and the body 105, and the first gate oxide 107a is close to the drain 106, the second gate oxide 107b is close to the source 103, and the spacing between the first gate oxide 107a and the second gate oxide 107b is denoted as spacing D107, wherein the first gate oxide 107a and the second gate oxide 107b are formed simultaneously by the same process. Specifically, the first gate oxide 107a and the second gate oxide 107b are formed in the same step using the same mask, and the thickness and material of the first gate oxide 107a and the second gate oxide 107b are the same. In an embodiment, the first gate oxide 107a and the second gate oxide 107b may comprise silicon dioxide or silicon nitride. In another embodiment, the first gate oxide 107a and the second gate oxide 107b may comprise one or more of some oxide materials, such as SiO₂, SOG, USG, BPSG, PSG and PETEOS. In an embodiment, the thickness of the first gate oxide 107a (denoted as d1) is 200 Å-500 Å. It should be appreciated that if the spacing D107 is too short, the peak electric field formed at the terminal of a second field plate 112b can not be effectively reduced, and if the spacing D107 is too long, the size of the LDMOS increases, so the spacing D107 needs to be precisely designed and controlled. In an embodiment, the spacing D107 is between 0.5 μm and 1.5 μm. In another embodiment, the spacing D107 is related to the breakdown voltage of the LDMOS.

The gate comprises a gate insulating layer 102 and a gate conducting layer 109, wherein the gate conducting layer 109 formed on the semiconductor substrate 101 and a portion of the second gate oxide 107b, the gate has a source side and a drain side. In an embodiment, the gate conducting layer 109 comprises polysilicon. In other embodiments, the gate conducting layer 109 may comprise combinations of some conductive materials. It should be understood that the gate insulating layer 102 and the first gate oxide 107a (the second gate oxide 107b) are marked in a different style in FIG. 1 is only for ease of identification, and in some embodiments, the gate insulating layer 102 and the first gate oxide 107a (the second gate oxide 107b) are of the same material. The thickness variation of the gate insulating layer 102 significantly affects the threshold voltage of the LDMOS, so the thickness of the gate insulating layer 102 is relatively fixed in a process, and it is not possible to adjust the thickness of the oxide layer under the field plates by adjusting the thickness of the gate insulating layer 102.

The field plate oxide layer 110 is disposed on the first gate oxide 107a, and the semiconductor substrate 101 between the first gate oxide 107a and the second gate oxide 107b. In an embodiment, the field plate oxide layer 110 is also disposed on a portion of the gate conducting layer 109. In an embodiment, the thickness of the field plate oxide layer 110 (denoted as d2) can be neither less than the thickness d1 of the first gate oxide 107a nor greater than 10 times the thickness d1 of the first gate oxide 107a. In an embodiment, the field plate oxide layer 110 comprises silicon dioxide and/or silicon nitride. In another embodiment, the field plate oxide layer 110 and the first gate oxide 107a, and the gate insulating layer 102 are all made of the same material.

The field plate barrier layer 111 is on the field plate oxide layer 110, and extends from the first gate oxide 107a to the second gate oxide 107b. In the embodiment shown in FIG. 1, the field plate barrier layer 111 extends to only a portion of the field plate oxide layer 110 on the second gate oxide 107b so as not to effect the subsequent effective ohmic contact in the gate conducting layer 109. In an embodiment, the field plate barrier layer 111 may comprise one or more of a group of non-conductive nitride, or other semiconductor nitride. In another embodiment, the field plate barrier layer 111 may comprise silicon nitride (Si₃N₄).

In the embodiment shown in FIG. 1, the LDMOS 100 also comprises a sidewall 114 and a metal silicide 115. In an embodiment, the sidewall 114 comprises nitride, such as SiN. In another embodiment, the sidewall 114 comprises an oxide, such as SiO₂, SiOC, etc. The sidewall 114 may be made of an insulating material or the same material as the gate conducting layer 109, depending on the purpose. When the sidewall 114 is configured to prevent a short circuit between metal silicide 115 (metal silicide 115 is formed by covering a thin layer of high conductivity material, such as tungsten or titanium, on the gate conducting layer 109, the source 103, the drain 106, and the body contact region 104), the sidewall 114 is made of an insulating material. When the sidewall 114 is configured to take block effect during injection, the sidewall 114 can be made of polysilicon. For example, when a low-voltage LDMOS is manufactured, the sidewall 114 is formed of polysilicon to block ion injection.

As in the embodiment shown in FIG. 1, the LDMOS 100 may also comprise a dielectric layer 113, a first field plate 112a, a second field plate 112b, a source contact 112c, and a drain contact 112d. In the embodiment shown in FIG. 1, the dielectric layer 113 has a upper surface S2 and overlies the field plate barrier layer 111, the gate, the source 103, and the drain 106. The first field plate 112a is located in the dielectric layer 113 above the first gate oxide 107a and extends from the field plate barrier layer 111 through the dielectric layer 113 to the upper surface S2 of the dielectric layer 113. The second field plate 112b is located in the dielectric layer 113 between the first gate oxide 107a and the second gate oxide 107b and extends from the field plate barrier layer 111 through the dielectric layer 113 to the upper surface S2 of the dielectric layer 113. The source contact 112c is formed in the dielectric layer 113 above the source 103 for coupling the source 103 to the desired potential terminal. The drain contact 112d is formed in the dielectric layer 113 above the drain 106 for coupling the drain 106 to the desired potential terminal. In an embodiment, the first field plate 112a comprises polysilicon or metal. In another embodiment, the first field plate 112a, the second field plate 112b, the source contact 112c, and the drain contact 112d have the same material and are manufactured in the same process step.

In the embodiment shown in FIG. 1, the first field plate 112a has a lower surface Sa in contact with the field plate barrier layer 111, and the second field plate 112b has a lower surface Sb in contact with the field plate barrier layer 111. The height of the lower surface Sa of the first field plate 112a to the upper surface S1 of the semiconductor substrate 101 is equal to the sum of the thickness d1 of the first gate oxide 107a and the thickness d2 of the field plate oxide layer 110 (usually the thickness of the field oxide 108, and a thickness d3 of the field plate barrier layer 111 are neglected here because it is relatively thin), and the height from the lower surface Sb of the second field plate 112b to the upper surface S1 of the semiconductor substrate 101 is equal to the thickness d2 of the field plate oxide layer 110, so it can be seen from the embodiment shown in FIG. 1 that the height difference between the height from the lower surface Sa to the upper surface S1 and the height from the lower surface Sb to the upper surface S1 is equal to the thickness d1 of the first gate oxide 107a. If the thickness d1 of the first gate oxide 107a is too thick, the peak electric field generated near the junction formed in the well 101b and the body 105 due to the curvature effect cannot be effectively reduced. If the thickness d1 of the first gate oxide 107a is too thin, the electric field distribution in the drift region 101b under the first field plate 112a and the second field plate 112b is not good. Therefore, a reasonable design of the thickness d1 of the first gate oxide 107a can effectively optimize the electric field distribution of the drift region 101b under the first field plate 112a and the second field plate 112b, and thus the peak electric field value is reduced and the breakdown voltage value of the LDMOS is increased.

It should be understood by those skilled in the art that the material, and regions listed above, such as the field plate barrier layer 111 and the dielectric layer 113, are merely examples for a better understanding of the present invention and are not intended to be limiting.

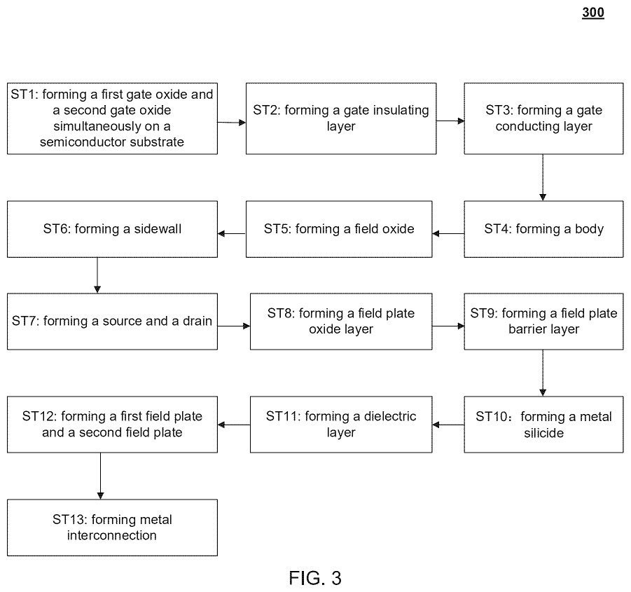

FIG. 2 illustrates a cross-sectional view of an LDMOS 200 according to an embodiment of the present invention. The description of the LDMOS 100 shown in FIG. 1 has described that the material of the first gate oxide 107a, the second gate oxide 107b, the gate insulating layer 102, the field oxide 108, and the dielectric layer 113 may be the same, the LDMOS 200 shown in FIG. 2 illustrates such an embodiment. Since the first gate oxide 107a, the second gate oxide 107b, the gate insulating layer 102, the field oxide 108, and the dielectric layer 113 are all of the same material, they are all referred to as an interlayer dielectric layer 213, and the other description can refer to the description in FIG. 1.

In FIG. 2, the LDMOS 200 comprises the well 101b formed in the semiconductor substrate 101, the body 105 formed in the well 101b, the source 103 formed in the body 105, and the drain 106. The semiconductor substrate 101 has the upper surface S1. The interlayer dielectric layer 213 covers the upper surface S1 of the semiconductor substrate 101 and has a upper surface S2. In an embodiment, the interlayer dielectric layer 213 comprises oxide or nitride. The LDMOS 200 comprises the gate conducting layer 109, the gate conducting layer 109 is located in the interlayer dielectric layer 213 between the source 103 and the drain 106. The gate conducting layer 109 comprises a plate portion 109a and a channel portion 109b, wherein the height of the plate portion 109a to the upper surface S1 of the semiconductor substrate 101 is greater than the height of the channel portion 109b to the upper surface S1 of the semiconductor substrate 101. The height of the plate portion 109a to the upper surface S1 of the semiconductor substrate 101 refers to the height H3 of the lower surface of the plate portion 109a to the upper surface S1 of the semiconductor substrate 101, and the height of the channel portion 109b to the upper surface S1 of the semiconductor substrate 101 refers to the height of the lower surface of the channel portion 109b to the upper surface S1 of the semiconductor substrate 101. The LDMOS 200 further comprises the field plate barrier layer 111, the first field plate 112a and the second field plate 112b, wherein the field plate barrier layer 111 is located in the interlayer dielectric layer 213 between the plate portion 109a and the drain 106. The first field plate 112a is disposed in the interlayer dielectric layer 213 and has the lower surface Sa in contact the field plate barrier layer 111. The first field plate 112a extends from the field plate barrier layer 111 through the interlayer dielectric layer 213 to the upper surface S2 of the interlayer dielectric layer 213. The second field plate 112b that is located in the interlayer dielectric layer 213 and has the lower surface Sb in contact with the field plate barrier layer 111. The second field plate 112b extends from the field plate barrier layer 111 through the interlayer dielectric layer 213 to the upper surface S2 of the interlayer dielectric layer 213. In FIG. 2, wherein the height H1 of the lower surface Sa of the first field plate 112a to the upper surface S1 of the semiconductor substrate 101 is greater than the height H2 of the lower surface Sb of the second field plate 112b to the upper surface S1 of the semiconductor substrate 101, and the height H2 of the lower surface Sb of the second field plate 112b to the upper surface S1 of the semiconductor substrate 101 is greater than the height H3 of the plate portion 109a to the upper surface S1 of the semiconductor substrate 101.

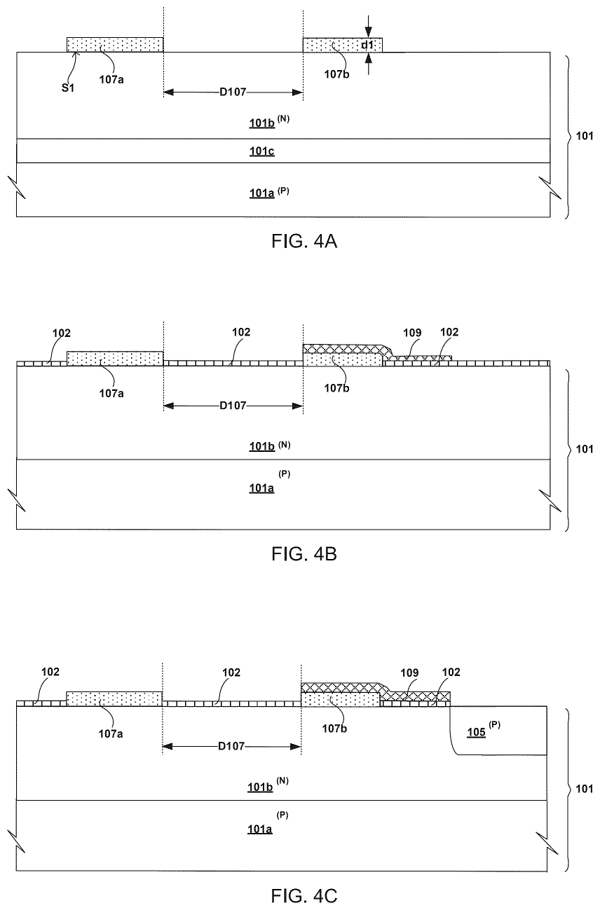

FIG. 3 illustrates a flow chart of a method 300 for manufacturing an LDMOS according to an embodiment of the present invention. The method 300 comprises steps ST1-ST13.
Step ST1: forming a first gate oxide and a second gate oxide simultaneously on a semiconductor substrate.
Step ST2: forming a gate insulating layer.
Step ST3: forming a gate conducting layer.
Step ST4: forming a body. In an embodiment, ion injection is used to form the body.
Step ST5: forming a field oxide.
Step ST6: forming a sidewall.
Step ST7: forming a source and a drain.
Step ST8: forming a field plate oxide layer.
Step ST9: forming a field plate barrier layer.
Step ST10: forming a metal silicide.
Step ST11: forming a dielectric layer.
Step ST12: forming a first field plate and a second field plate.
Step ST13: forming metal interconnection.

It should be known to those skilled in the art that FIG. 3 only exemplifies some exemplary steps, some additional steps may be required in order to improve the specific performance of the LDMOS. Some subsequent steps, such as the step of forming multilayer metal interconnection may be required to form the potential connection of the source and the drain of the LDMOS, which are not described in detail here.

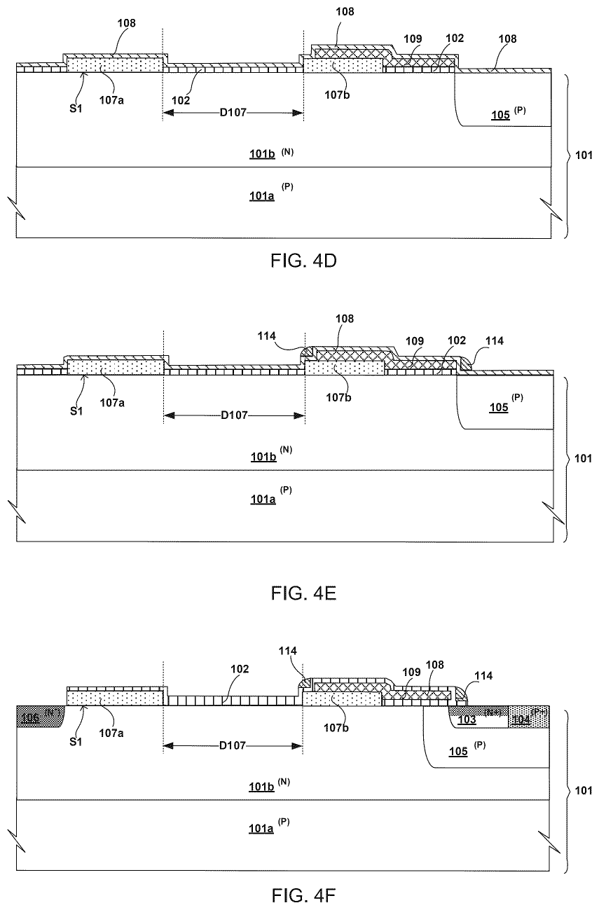

FIGS. 4A-4K illustrate a cross-sectional view of an LDMOS in some steps of the method 300 according to an embodiment of the present invention’.

Step ST1 in the method 300, the first gate oxide 107a and the second gate oxide 107b are formed simultaneously on semiconductor substrate 101 as shown in FIG. 4A. As shown in FIG. 4A, the semiconductor substrate 101 comprises the initial substrate 101a, the well 101b and a buried layer 101c, wherein the well 101b is also referred to as the drift region 101b. In an embodiment, the initial substrate 101a may be silicon, germanium, SiC or any suitable semiconductor material. In an embodiment, the buried layer 101c is N-type and can reduce the leakage current and parasitic parameters of the LDMOS. It should be noted that the semiconductor substrate 101 illustrated in FIG. 4A is only for exemplary, when a PMOS device is integrated in the semiconductor substrate 101, the semiconductor substrate 101 may have other regions.

Continuing with the illustration of FIG. 4A, the first gate oxide 107a and the second gate oxide 107b are formed simultaneously on the well 101b, wherein the first gate oxide 107a and the second gate oxide 107b have the same thickness and material. In an embodiment, the step of forming the first gate oxide 107a and the second gate oxide 107b comprises a step of forming a gate oxide layer by chemical vapor deposition or thermal growth, and a step of forming a desired shape by a photolithography process and an etching process, wherein the photolithography process comprises: applying a photoresist to the gate oxide layer, exposing to UV with the gate oxide mask, and etching of the exposed photoresist. In an embodiment, the first gate oxide 107a has the thickness d1 in a range from 200 Å to 500 Å. If the first gate oxide 107a is too thick, the peak electric field generated near the junction formed in the drift region 101b and the body 105 (subsequently generated) cannot be effectively reduced due to the curvature effect. If the first gate oxide 107a is too thin, the height difference between the height of the first field plate 112a to the upper surface S1 of the semiconductor substrate 101 and the height of the second field plate 112b to the upper surface S1 of the semiconductor substrate 101 is not obvious, and the electric field distribution in the drift region 101b under the first field plate 112a and the second field plate 112b is not good, so the thickness d1 of the first gate oxide 107a (and the thickness d1 of the second gate oxide 107b) needs to be precisely controlled and designed. It should be known that if the spacing D107 between the first gate oxide 107a and the second gate oxide 107b is too short, the secondary peak electric field formed at the terminal of the second field plate 112b due to the second field plate 112b cannot be effectively reduced, and if the spacing D107 is too long, the size of the LDMOS will be increased significantly, so the spacing D107 between the first gate oxide 107a and the second gate oxide 107b also needs to be precisely designed and controlled. In an embodiment, the spacing D107 between the first gate oxide 107a and the second gate oxide 107b is between 0.5 μm and 1.5 μm. In another embodiment, the spacing D107 between the first gate oxide 107a and the second gate oxide 107b is related to the size of the LDMOS and the breakdown voltage of the LDMOS.

In FIGS. 4B to 4K, the N-type buried layer 101c is not shown for clarity, and the semiconductor substrate 101 is only selectively exemplified with the initial substrate 101a and the well 101b.

Referring to FIG. 4B, step ST3 for forming the gate conducting layer 109 in method 300 is described. It is to be appreciated that step ST2 of forming for the gate insulating layer 102 is required prior to step ST3. In an embodiment, the gate insulating layer 102 is formed by thermal growth. In an embodiment, the thickness of the gate insulating layer 102 is between 60 Å and 200 Å. In the embodiment shown in FIG. 4B, forming the gate conducting layer 109 comprises forming the gate conductive layer by chemical vapor deposition and forming the gate conducting layer 109 by a photolithography process and an etching process.

Referring to FIG. 4C, step ST4 for forming the body 105 in method 300 is described. In an embodiment, forming the body 105 requires a photolithography process and ion implantation. In an embodiment, the gate insulating layer 102 and the gate conducting layer 109 together are defined as the gate of the LDMOS, the gate has the source side and the drain side. The body 105 is formed in the semiconductor substrate 101 on the source side of the gate.

Referring to FIG. 4D, step ST5 for forming field oxide 108 in method 300 is described. In an embodiment, the field oxide 108 is formed by thermal growth or chemical vapor deposition. The field oxide 108 covers the surface of the gate conducting layer 109 to provide protection for the gate conducting layer 109.

Referring to FIG. 4E, step ST6 for forming the sidewall 114 in method 300 is described. A sidewall layer is deposited on the field oxide 108, and after etching of the sidewall layer, the sidewall 114 is formed on the side of the gate conducting layer 109. In an embodiment, the sidewall 114 comprises nitride. In another embodiment, the sidewall 114 comprises oxide, such as SiO₂, SiOC, etc.

Because the field oxide 108 and the gate insulating layer 102 typically comprise the same material, such as a mixture of silicon dioxide and silicon nitride, portions of the gate insulating layer 102 and the field oxide 108 in FIGS. 4F-4K are no longer shown separately, but only the gate insulating layer 102 is denoted for clarity.

Referring to FIG. 4F, step ST7 for forming the source 103 and the drain 106 in method 300 is described. In the embodiment shown in FIG. 4F, ion injection is used to form the source 103 and the drain 106. In the embodiment shown in FIG. 4F, an ion injection of the second conductivity type is performed to form the source 103 and the drain 106, and an ion injection of the first conductivity type is followed to form the body contact region 104. In an embodiment, the drain 106 is formed in the semiconductor substrate 101 on the drain side of the gate.

Referring to FIG. 4G, step ST8 for forming the field plate oxide layer 110 in method 300 is described. In an embodiment, the field plate oxide layer 110 is formed by thermal growth or chemical vapor deposition. In an embodiment, the field plate oxide layer 110, the field oxide 108, the gate insulating layer 102, and the first gate oxide 107a comprise the same material. In an embodiment, the field plate oxide layer 110 comprises a mixture of silicon dioxide and silicon nitride. In an embodiment, the thickness d2 of the field plate oxide layer 110 is between 500 Å-2000 Å. In an embodiment, the height of the lower surface Sb of the second field plate 112b (subsequently generated) to the upper surface S1 of the semiconductor substrate 101, the thickness of the oxide layer between the second field plate 112b and the upper surface S1 of the semiconductor substrate 101, can be changed by varying the thickness of the field plate oxide layer 110, thereby affecting the electric field distribution in the well 101b under the second field plate 112b, so the thickness of the field plate oxide layer 110 are required to be precise controlled and designed.

Referring to FIG. 4H, step ST9 for forming the field plate barrier layer 111 in method 300 is described. In the embodiment shown in FIG. 4H, the field plate barrier layer 111 is formed by chemical vapor deposition of nitride. It is noted that the field plate barrier layer 111 may be not so thick as to affect the subsequent formation of an effective ohmic contact in the gate conducting layer 109. In an embodiment, the field plate barrier layer 111 has the thickness d3 between 200 Å and 500 Å.

Referring to FIG. 4I, step ST10 of forming the metal silicide 115 in method 300 is described. In an embodiment, the metal silicide 115 may be formed by covering the surface of the gate conducting layer 109 and the active region (source 103, drain 106, body contact region 104, etc.) with a thin layer of a high conductivity material, such as titanium silicide or tungsten silicide.

Referring to FIG. 4J, step ST11 for forming the dielectric layer 113 in method 300 is described. In an embodiment, the dielectric layer 113 is formed by chemical vapor deposition. In another embodiment, the dielectric layer 113, the field plate oxide layer 110, the field oxide 108 and the gate insulating layer 102 comprises the same material. In an embodiment, the dielectric layer 113 comprises a mixture of silicon dioxide and silicon nitride.

Referring to FIG. 4K, step ST12 for forming the first field plate 112a and the second field plate 112b in method 300 is described. In an embodiment, the first field plate 112a and the second field plate 112b are formed by a photolithography process, an etching process, and a metal deposition. Wherein the photolithography process comprises: applying a photoresist, exposing to UV with a field plate mask version, etc. In an embodiment, the etching process comprises etching the dielectric layer 113 in vertical until it encounters the field plate barrier layer 111. In an embodiment, the metal deposition comprises depositing tungsten or titanium.

For the LDMOS having the first field plate 112a and the second field plate 112b in accordance with various embodiments of the present invention, the oxide layer under the first field plate 112a is thicker than the oxide layer under the second field plate 112b, the electric field distribution in the drift region under the first field plate 112a and the second field plate 112b is optimized, thus the peak of the electric field is reduced and the breakdown voltage of the LDMOS is increased.

For the LDMOS having the first field plate 112a and the second field plate 112b in accordance with various embodiments of the present invention, the first gate oxide 107a and the second gate oxide 107b are formed by the same mask at the same time, so the performance of the LDMOS device is improved with no increase on the manufacturing cost.

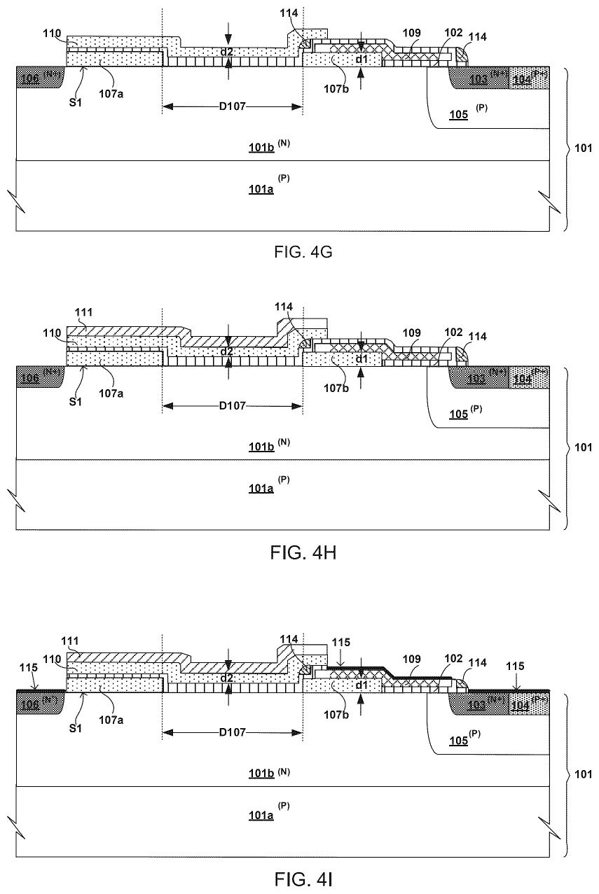

FIG. 5 illustrates a cross-sectional view of an LDMOS 500 according to an embodiment of the present invention. The LDMOS 500 includes the semiconductor substrate 101. The semiconductor substrate 101 includes the source 103, the drain 106, the body 105, the initial substrate 101a and the drift region 101b. In some embodiment, the semiconductor substrate 101 further includes the buried layer 101c as shown in FIG. 4A. In some embodiments, the initial substrate 101a and the body 105 have the first conductivity type, and the source 103, the drain 106, and the drift region 101b have the second conductivity type opposite to the first conductivity type. In some embodiments, the first conductivity type is P-type and the second conductivity type is N-type. In other embodiments, the first conductivity type is N-type and the second conductivity type is P-type. In one embodiment, the source 103 and the drain 106 have a heavier doping concentration than the drift region 101b (e.g., denoted by N+ in FIG. 5). As shown in FIG. 5, the body 105 is positioned between the source 103 and the drain 106, the drift region 101b is positioned between the body 105 and the drain 106. In one embodiment, the semiconductor substrate 101 further includes the body contact 104 having the first conductivity type. The body contact 104 is positioned in the body 105 and has a heavier doping concentration than the body 105 (e.g., denoted by P+ in FIG. 5)

In the embodiment of FIG. 5, the LDMOS 500 further includes the gate, a gate oxide 107, a first field plate oxide layer 110a, a second field plate oxide layer 110b, a third field plate oxide layer 110c, a first field plate barrier layer 111-1a, a second field plate barrier layer 111-1b, a third field plate barrier layer 111-1c, and a fourth field plate barrier layer 111-2.

The gate oxide 107 is positioned atop the semiconductor substrate 101. In the embodiment shown in FIG. 5, a first side (e.g., the left side) of the gate oxide 107 is close to the drain 106, and a second side (e.g., the right side) of the gate oxide 107 is close to the body 105. In one embodiment, the gate oxide 107 extends laterally from atop the drain 106 to underneath the gate. In one embodiment, the gate oxide 107 may include silicon dioxide. In an embodiment, the thickness of the gate oxide 107 ranges from 200 Å to 500 Å.

The gate is positioned between the source 103 and the drain 106 and at least positioned atop the body 105. In the embodiment shown in FIG. 5, the gate is positioned atop the semiconductor substrate 101 close to the source 103. The gate includes the gate conducting layer 109 and the gate insulating layer 102. The gate conducting layer 109 extends laterally from atop the gate oxide 107 to atop the source 103. The gate insulating layer 102 is positioned between the gate conducting layer 109 and the semiconductor substrate 101. In the embodiment of the present disclosure, the gate conducting layer 109 includes the plate portion 109a and the channel portion 109b. In one embodiment, the plate portion 109a is positioned atop the gate oxide 107, and the channel portion 109b is positioned atop the gate insulating layer 102. In one embodiment, the gate conducting layer 109 includes polysilicon. In other embodiments, the gate conducting layer 109 may include other conductive materials (e.g., metals, other semiconductors, semi-metals. and/or combinations thereof) that are compatible with other aspects of the device manufacturing process. It should be understood that the gate insulating layer 102 and the gate oxide 107 are marked in a different style in FIG. 5 is only for ease of identification. In some embodiments, the material of the gate insulating layer 102 and the gate oxide 107 are made of the same material.

The first field plate oxide layer 110a is positioned atop the drain 106 and the gate oxide 107, and is close to the first side (e.g., the left side) of the gate oxide 107. The second field plate oxide layer 110b is positioned atop the gate oxide 107 and the gate, and is close to the second side (e.g., the right side) of the gate oxide 107. The second field plate oxide layer 110b may be connected/combined with the gate oxide 107 and the gate insulating layer 102 to wrap the gate conducting layer 109. As shown in FIG. 5, there is a spacing D108 between the first field plate oxide layer 110a and the second field plate oxide layer 110b. In practical applications, the spacing D108 may be set based on parameters (e.g., breakdown voltage) of the LDMOS 500. In some embodiments, the spacing D108 is in a range of 0.1 μm to 5.0 μm. In some embodiments, the first field plate oxide layer 110a and the second field plate oxide layer 110b are formed simultaneously in the same process, that is to say, the first field plate oxide layer 110a and the second field plate oxide layer 110b have the same thickness and material. Forming simultaneously in the same process refers that the first field plate oxide layer 110a and the second field plate oxide layer 110b are formed using the same mask in the same step. In one embodiment, the first field plate oxide layer 110a and the second field plate oxide layer 110b are twice as thick as the gate oxide 107. In one embodiment, the first field plate oxide layer 110a and the second field plate oxide layer 110b are made of the same material as the gate oxide 107 and the gate insulating layer 102.

The first field plate barrier layer 111-1a and the second field plate barrier layer 111-1b are positioned atop the first field plate oxide layer 110a and the second field plate oxide layer 110b, respectively. In some embodiments, the first field plate barrier layer 111-1a and the second field plate barrier layer 111-1b are formed simultaneously in the same process, thus they have the same thickness and material. In one embodiment, the first field plate barrier layer 111-1a has the thickness of 100 Å-600 Å. In one embodiment, both the first field plate barrier layer 111-1a and the second field plate barrier layer 111-1b have the thickness of 400 Å.

The third field plate barrier layer 111-1c is positioned atop the first field plate barrier layer 111-1a, the second field plate barrier layer 111-1b, and the spacing D108 between the first field plate oxide layer 110a and the second field plate oxide layer 110b. In one embodiment, the thickness of the third field plate barrier layer 111-1c is less than the thickness of the first field plate barrier layer 111-1a. In one embodiment, the thickness of the third field plate barrier layer 111-1c is 100 Å-600 Å. In one embodiment, the material of the third field plate barrier layer 111-1c is the same as that of the first field plate barrier layer 111-1a.

In some embodiments of the present disclosure, one mask (e.g., a first mask) is needed during the formation of the first field plate oxide layer 110a and the second field plate oxide layer 110b, as well as the first field plate barrier layer 111-1a and the second field plate barrier layer 111-1b. In other words, the first mask defines the region in which the first field plate oxide layer 110a, the second field plate oxide layer 110b, the first field plate barrier layer 111 and the second field plate barrier layer 111-1b are positioned. Accordingly, the spacing between the first field plate barrier layer 111-1a and the second field plate barrier layer 111-1b is equal to the spacing D108 between the first field plate oxide layer 110a and the second field plate oxide layer 110b. It should be appreciated that, in some embodiments, the thickness of a portion of the gate oxide 107 below the spacing D108 may be reduced during the formation of the first field plate oxide layer 110a and the second field plate oxide layer 110b, and/or the first field plate barrier layer 111-1b and the second field plate barrier layer 111-1b. In other words, the thickness of the portion of the gate oxide 107 below the spacing D108 may be less than the thickness of other portions of the gate oxide 107. For instance, when the original thickness of the gate oxide 107 is 400 Å, the thickness of the gate oxide 107 below the spacing D108 may be reduced to 200 Å.

The third field plate oxide layer 110c is positioned atop the third field plate barrier layer 111-1c and includes a first portion and a second portion. The first portion of the third field plate oxide layer 110c is positioned atop the first field plate oxide layer 110a, and the second portion of the third field plate oxide layer 110c is positioned atop the spacing D108 between the first field plate oxide layer 110a and the second field plate oxide layer 110b. As shown in FIG. 5, the width of the first portion of the third field plate oxide layer 110c is labelled to W1. The thickness of the third field plate oxide layer 110c may be set according to parameters (e.g., rated voltage) of the LDMOS 500. In one embodiment, the thickness of the third field plate oxide layer 110c is in a range of 800 Å to 3000 Å. In one embodiment, the third field plate oxide layer 110c includes silicon dioxide and/or silicon nitride. In another embodiment, the material of the third field plate oxide layer 110c is the same as that of the first field plate oxide layer 110a and the second field plate oxide layer 110b.

The fourth field plate barrier layer 111-2 is positioned atop the third field plate oxide layer 110c. In one embodiment, the thickness of the fourth field plate barrier layer 111-2 is less than the thickness of the first field plate barrier layer 111-1a. In one embodiment, the thickness of the fourth field plate barrier layer 111-2 is in a range of 100 Å to 600 Å. In one embodiment, the material of the fourth field plate barrier layer 111-2 is the same as that of the first field plate barrier layer 111-1a.

It should be appreciated that in embodiments of the present disclosure, the field plate barrier layer 111 (e.g., the first field plate barrier layer 111-1a, the second field plate barrier layer 111-1b, the third field plate barrier layer 111-1c, and the fourth field plate barrier layer 111-2 shown in FIG. 5) is configured to protect the corresponding field plate oxide layer 110 (e.g., the first field plate oxide layer 110a, the second field plate oxide layer 110b, and the third field plate oxide layer 110c shown in FIG. 5) underneath it from being damaged in subsequent etching process. Therefore, it should be appreciated by those of ordinary skill in the art that the composition of the field plate barrier layer 111 may include a material having a high etch selectivity ratio with respect to the oxide. Also, the thickness of the field plate barrier layer 111 could be adjusted according to practical applications. In one embodiment, the field plate barrier layer 111 may include one or more of a group of non-conductive nitrides such as nitrides or other semiconductor nitrides. In another embodiment, the field plate barrier layer 111 may include one or more of a group of non-conductive carbides such as carbides or other semiconductor carbides. In yet another embodiment, the field plate barrier layer 111 may include one or more compounds from the above-described nitride group, carbide group, and nitrogen oxide group.

In some embodiments of the present disclosure, one mask (e.g., a second mask) is needed during the formation of the third field plate oxide layer 110c and the fourth field plate barrier layer 111-2. In other words, the second mask defines the region in which the third field plate oxide layer 110c and the fourth field plate barrier layer 111-2 are positioned. Notably, the size and relative position of the regions defined by the first mask and the second mask need to be precisely designed and controlled to ensure that the third field plate oxide layer 110c and the fourth field plate barrier layer 111-2 could be formed atop the first field plate oxide layer 110a as well as the spacing D108 between the first field plate oxide layer 110a and the second field plate oxide layer 110b.

In the embodiment shown in FIG. 5, the LDMOS 500 further includes the sidewall 114 and the metal silicide 115. The metal silicide 115 is the thin layer including highly conductive material and covers over the gate conducting layer 109, the source 103, the body contact 104, and the drain 106. In one embodiment, the metal silicide 115 is formed by reacting a refractory metal with silicon, including one or some of tungsten silicide, titanium silicide, tantalum silicide, and cobalt silicide. The sidewall 114 are positioned on both sides of the gate conducting layer 109 and isolated from the gate conducting layer 109 by the field oxide 108. In some embodiments, the material of the field oxide 108 is the same as that of the gate insulating layer 102 and the gate oxide 107. The sidewall 114 may be made of an insulating material or the same material as the gate conducting layer 109 depending on the purpose. When the sidewall 114 is used to prevent a short circuit between the metal silicide 115, the sidewall 114 is made of the insulating material (e.g., oxide). When the sidewall 114 is used to take block effect during injection, the sidewall 114 is made of polysilicon. For example, during the manufacturing process of a low-voltage LDMOS, the sidewall 114 formed by polysilicon is used to block ion injection for improving the contact between the source 103 and the channel of the LDMOS 500. In one embodiment, the sidewall 114 includes the nitride, such as SiN. In another embodiment, the sidewall 114 includes oxide, such as SiO₂, SiOC, and the like. In one embodiment, the material of the sidewall 114 is the same as the first field plate barrier layer 111-1a. In one embodiment, because of incomplete etching, a remained field plate oxide layer 110r is left during the formation of the first field plate oxide layer 110a and the second field plate oxide layer 110b. As shown in FIG. 5, the remained field plate oxide layer 110r is between the sidewall 114 and the metal silicide 115 atop the source 103.

In the embodiment shown in FIG. 5, the LDMOS 500 further includes the dielectric layer 113, the first field plate 112a, the second field plate 112b, a third field plate 112e, the source contact 112c, and the drain contact 112d. The dielectric layer 113 is positioned atop the third field plate barrier layer 111-1c and the fourth field plate barrier layer 111-2 and has the upper surface S2. The first field plate 112a is positioned in the dielectric layer 113 atop the first field plate oxide layer 110a, and the lower surface Sa of the first field plate 112a is in contact with the fourth field plate barrier layer 111-2. The second field plate 112b is positioned in the dielectric layer 113 atop the spacing D108 between the first field plate oxide layer 110a and the second field plate oxide layer 110b, and the lower surface Sb of the second field plate 112b is in contact with the fourth field plate barrier layer 111-2. The third field plate 112e is positioned in the dielectric layer 113 atop the second field plate oxide layer 110b, and a lower surface Se of the third field plate 112e is in contact with the third field plate barrier layer 111-1c. In the embodiments of the present disclosure, the lower surface of each field plate may be in contact with the upper surface, the lower surface, or the middle portion between the upper and lower surfaces of the corresponding field plate barrier layer. For example, in one embodiment, the lower surface Sa of the first field plate 112a is in contact with the upper surface of the fourth field plate barrier layer 111-2. In another embodiment, the lower surface Sa of the first field plate 112a is in contact with the lower surface of the fourth field plate barrier layer 111-2. In yet another embodiment, the lower surface Sa of the first field plate 112a is in contact with the middle portion between the upper and lower surfaces of the fourth field plate barrier layer 111-2.

As shown in FIG. 5, the first field plate 112a extends vertically from the fourth field plate barrier layer 111-2 through the dielectric layer 113 to the upper surface S2 of the dielectric layer 113. The second field plate 112b extends vertically from the fourth field plate barrier layer 111-2 through the dielectric layer 113 to the upper surface S2 of the dielectric layer 113. The third field plate 112e extends vertically from the third field plate barrier layer 111-1c through the dielectric layer 113 to the upper surface S2 of the dielectric layer 113. The source contact 112c is positioned in the dielectric layer 113 atop the source 103 for coupling the source 103 to a desired potential terminal. The drain contact 112d is positioned in the dielectric layer 113 atop the drain 106 for coupling the drain 106 to a desired potential terminal. In one embodiment, the first field plate 112a, the second field plate 112b the third field plate 112e may include suitable conductive materials. In one embodiment, the first field plate 112a includes polysilicon or metal. In another embodiment, the first field plate 112a, the second field plate 112b, the third field plate 112e, the source contact 112c, and the drain contact 112d are made of the same material and formed in the same process.

In the embodiment shown in FIG. 5, the first field plate 112a, and the corresponding portions of the fourth field plate barrier layer 111-2, the third field plate oxide layer 110c, the third field plate barrier layer 111-1c, the first field plate barrier layer 111-1a, the first field plate oxide layer 110a, and the gate oxide 107 underneath the first field plate 112a could be regarded as a first-step field plate structure. The second field plate 112b, and the corresponding portions of the fourth field plate barrier layer 111-2, the third field plate oxide layer 110c, the third field plate barrier layer 111-1c, and the gate oxide 107 underneath the second field plate 112b could be regarded as a second-step field plate structure. The third field plate 112e and the corresponding portions of the third field plate barrier layer 111-1c, the second field plate barrier layer 111-1b, the second field plate oxide layer 110b, and the gate oxide 107 underneath the third field plate 112e could be regarded as a third-step field plate structure. The field plate region 109a of the gate conducting layer 109 and the portion of the gate oxide 107 underneath the field plate region 109a could be regarded as a fourth-step field plate structure. That is, the LDMOS 500 shown in FIG. 5 has a four-steps field plate structure, and the thickness of the insulating layer under the field plates increases sequentially from the gate to the drain 106.

Specifically, the height H1 of the lower surface Sa of the first field plate 112a to the upper surface S1 of the semiconductor substrate 101 is greater than the height H2 of the lower surface Sb of the second field plate 112b to the upper surface S1 of the semiconductor substrate 101, the height H2 of the lower surface Sb of the second field plate 112b to the upper surface S1 of the semiconductor substrate 101 is greater than a height H4 of the lower surface Se of the third field plate 112e to the upper surface S1 of the semiconductor substrate 101, and the height H4 of the lower surface Se of the third field plate 112e to the upper surface S1 of the semiconductor substrate 101 is greater than the height H3 of the plate portion 109a to the upper surface S1 of the semiconductor substrate 101.

In embodiments of the present disclosure, the number of the first field plate 112a, the second field plate 112b, and the third field plate 112e may be set according to the application requirements.

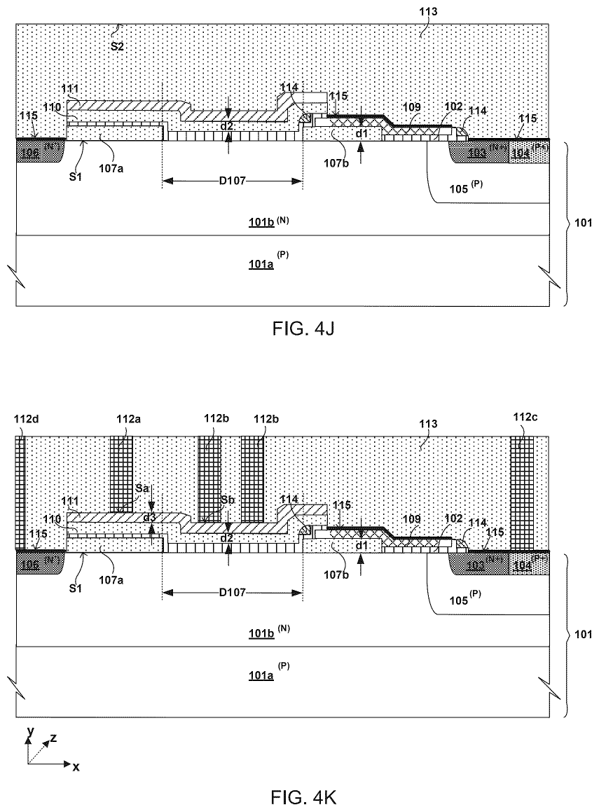

FIG. 6 illustrates a cross-sectional view of an LDMOS 600 according to another embodiment of the present invention. Compared to the embodiment of FIG. 5, in the embodiment of FIG. 6, the LDMOS 600 includes two first field plates 112a, 112a′ and two third field plates 112e, 112e′. In the embodiment of FIG. 6, a width W2 of the first portion of a third field plate oxide layer 110c′ positioned atop the first field plate oxide layer 110a is greater than the width W1 of the first portion of the third field plate oxide layer 110c in the embodiment of FIG. 5. In other words, the width of the third field plate oxide layer 110c defined by the second mask is increased in the embodiment of FIG. 6 compared with that of the embodiment of FIG. 5. It should be understood that the number of field plates may be flexibly adjusted by designing the size and relative position of the areas defined by the first mask and the second mask. The number of field plates described in various embodiments of the present disclosure are illustrative and not intended to be limiting.

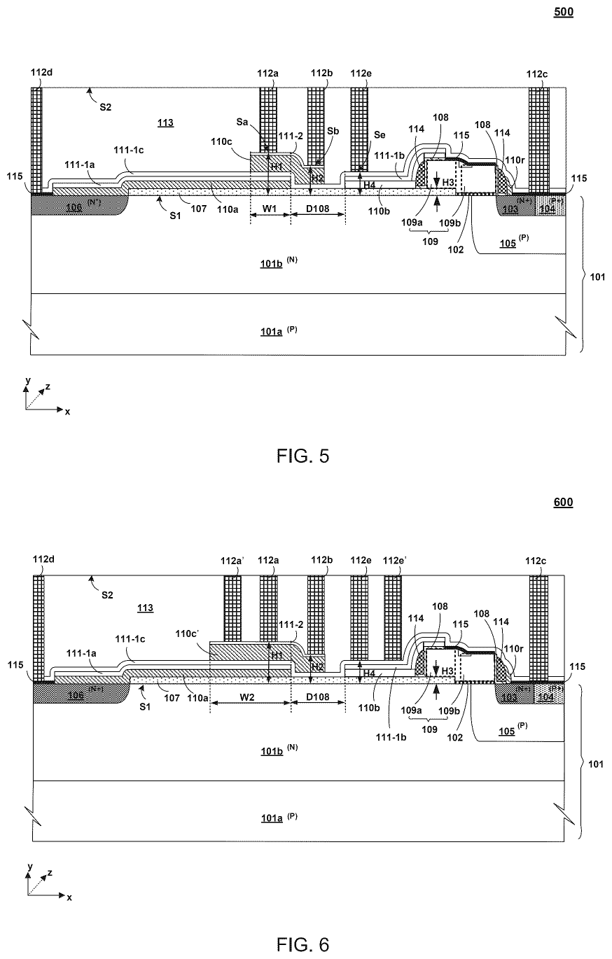

FIG. 7 illustrates a cross-sectional view of an LDMOS 700 according to an embodiment of the present invention. In the embodiment of FIG. 7, the LDMOS 700 further includes a first metal interconnection layer 116 and a second metal interconnection layer 117. The first metal interconnection layer 116 is positioned in the dielectric layer 113 atop the source contact 112c, and the second metal interconnection layer 117 is positioned in the dielectric layer 113 atop the drain contact 112d. In the embodiment of FIG. 7, the first metal interconnection layer 116 is configured to electrically couple the first field plate 112a, the second field plate 112, and the third field plate 112e to the source contact 112c, such that the potentials of the first field plate 112a, the second field plate 112, and the third field plate 112e are the same as the that of the source 103. It should be appreciated that the first field plate 112a, the second field plate 112 and the third field plate 112e may be electrically coupled to other suitable potentials as required for practical applications. As shown in FIG. 7, the first field plate 112a extends vertically from the fourth field plate barrier layer 111-2 through the dielectric layer 113 to a lower surface S3 of the first metal interconnection layer 116. The second field plate 112b extends vertically from the fourth field plate barrier layer 111-2 through the dielectric layer 113 to the lower surface S3 of the first metal interconnection layer 116. The third field plate 112e extends vertically from the third field plate barrier layer 111-1c through the dielectric layer 113 to the lower surface S3 of the first metal interconnection layer 116.

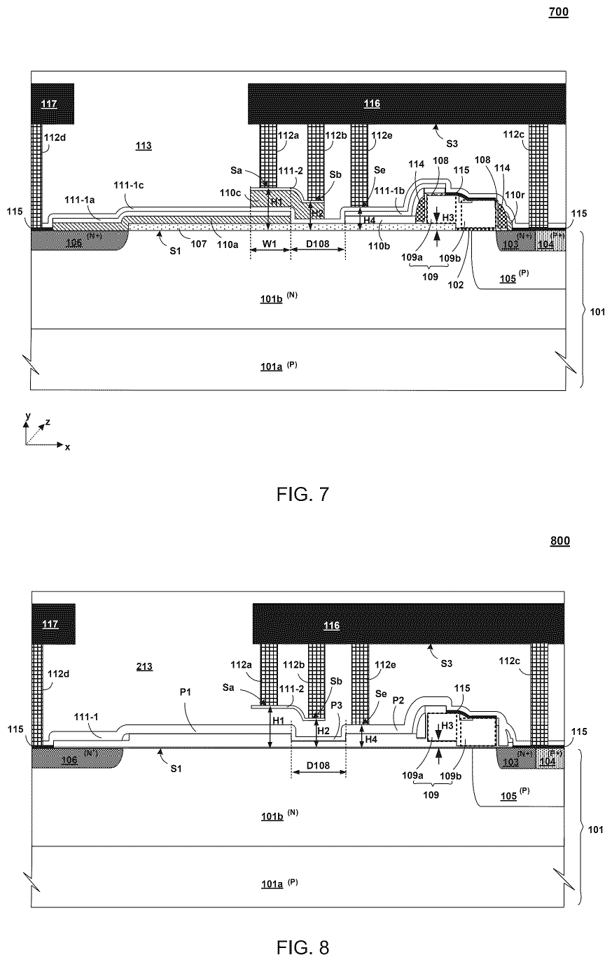

FIG. 8 illustrates a cross-sectional view of an LDMOS 800 according to an embodiment of the present invention. The description of the LDMOS 500 shown in FIG. 5 has described that the material of the gate oxide 107, the gate insulating layer 102, the field oxide 108, the first field plate oxide layer 111a, the second field plate oxide layer 111b, the third field plate oxide layer 111c, and the dielectric layer 113 may be the same. Meanwhile, the material of the first field plate barrier layer 111-1a, the second field plate barrier layer 111-1b, the third field plate barrier layer 111-1c, the fourth field plate barrier layer 111-2 and the sidewall 114 may be the same. The LDMOS 800 shown in FIG. 8 illustrates such an embodiment. Since the gate oxide 107, the gate insulating layer 102, the field oxide 108, the first field plate oxide layer 111a, the second field plate oxide layer 111b, the third field plate oxide layer 111c, and the dielectric layer 113 are made of the same material, they are marked as the same style and referred as an interlayer dielectric layer 213. Since the first field plate barrier layer 111-1a, the second field plate barrier layer 111-1b, the third field plate barrier layer 111-1c, the fourth field plate barrier layer 111-2, and the sidewall 114 are made of the same material, they are marked as another style. Furthermore, the first field plate barrier layer 111-1a, the second field plate barrier layer 111-1b, the third field plate barrier layer 111-1c are referred as a low side field plate barrier layer 111-1, and the fourth field plate barrier layer 111-2 are referred as a high side field plate barrier layer 111-2. Other descriptions could refer to the description in FIG. 5.

In the embodiment of FIG. 8, the LDMOS 800 includes the semiconductor substrate 101. The semiconductor substrate 101 includes the source 103, the drain 106, the body 105, the initial substrate 101a and the drift region 101b. As shown in FIG. 8, the body 105 is positioned between the source 103 and the drain 106, the drift region 101b is positioned between the body 105 and the drain 106. In the embodiment of FIG. 8, the LDMOS 800 further includes the interlayer dielectric layer 213, the gate conducting layer 109, the low side field plate barrier layer 111-1, and the high side field plate barrier layer 111-2. The interlayer dielectric layer 213 is positioned atop the semiconductor substrate 101. In one embodiment, the interlayer dielectric layer 213 includes oxide. The gate conducting layer 109 is positioned between the source 103 and the drain 106 and includes the plate portion 109a and the channel portion 109b. The height H3 of the plate portion 109a to the upper surface S1 of the semiconductor substrate 101 is greater than the height of the channel portion 109b to the upper surface S1 of the semiconductor substrate 101. The low side field plate barrier layer 111-1 is positioned in the interlayer dielectric layer 213 and includes a first portion P1, a second portion P2 and a third portion P3. The first portion P1 of the low side field plate barrier layer 111-1 is positioned in the interlayer dielectric layer 213 close to the drain 106, the second portion P2 of the low side field plate barrier layer 111-1 is positioned in the interlayer dielectric layer 213 close to the source 103, and the third portion P3 of the low side field plate barrier layer 111-1 is positioned between the first portion P1 and the second portion P2. In one embodiment, the width of the third portion P3 is equal to the spacing D108. The high side field plate barrier layer 111-2 is positioned in the interlayer dielectric layer 213 atop the first portion P1 and the third portion P3 of the low side field plate barrier layer 111-1. In one embodiment, the low side field plate barrier layer 111-1 includes nitride. In one embodiment, the low side field plate barrier layer 111-1 and the high side field plate barrier layer 111-2 are made of the same material.

In the embodiment of FIG. 8, the LDMOS 800 further includes the first field plate 112a, the second field plate 112b, the third field plate 112e, the source contact 112c, and the drain contact 112d. As shown in FIG. 8, the first field plate 112a is positioned in the interlayer dielectric layer 213 atop the first portion P1 of the low side field plate barrier layer 111-1, and the lower surface Sa of the first field plate 112a is in contact with the high side field plate barrier layer 111-2. The second field plate 112b is positioned in the interlayer dielectric layer 213 atop the third portion P3 of the low side field plate barrier layer 111-1, and the lower surface Sb of the second field plate 112b is in contact with the high side field plate barrier layer 111-2. The third field plate 112e is positioned in the interlayer dielectric layer 213 atop the second portion P2 of the low side field plate barrier layer 111-1, and the lower surface Se of the third field plate 112e is in contact with the low side field plate barrier layer 111-1. In the embodiment of FIG. 8, the height H1 of the lower surface Sa of the first field plate 112a to the upper surface S1 of the semiconductor substrate 101 is greater than the height H2 of the lower surface Sb of the second field plate 112b to the upper surface S1 of the semiconductor substrate 101, the height H2 of the lower surface Sb of the second field plate 112b to the upper surface S1 of the semiconductor substrate 101 is greater than the height H4 of the lower surface Se of the third field plate 112e to the upper surface S1 of the semiconductor substrate 101, and the height H4 of the lower surface Se of the third field plate 112e to the upper surface S1 of the semiconductor substrate 101 is greater than the height H3 of the lower surface of the plate portion 109a to the upper surface S1 of the semiconductor substrate 101. In other words, the LDMOS 800 shown in FIG. 8 has the four-steps field plate structure.

In the embodiment of FIG. 8, the LDMOS 800 further includes the first metal interconnection layer 116 and the second metal interconnection layer 117. The first metal interconnection layer 116 is positioned in the interlayer dielectric layer 213 atop the source contact 112c, and the second metal interconnection layer 117 is positioned in the interlayer dielectric layer 213 atop the drain contact 112d. As shown in FIG. 8, the first field plate 112a extends vertically from the high side field plate barrier layer 111-2 through the interlayer dielectric layer 213 to the lower surface S3 of the first metal interconnection layer 116. The second field plate 112b extends vertically from the high side field plate barrier layer 111-2 through the interlayer dielectric layer 213 to the lower surface S3 of the first metal interconnection layer 116. The third field plate 112e extends vertically from the low side field plate barrier layer 111-1 through the interlayer dielectric layer 213 to the lower surface S3 of the first metal interconnection layer 116.

The LDMOS described in embodiments of the present disclosure has a multi-step field plate structure. In the multi-step field plate structure, the thickness of the insulating layer increases sequentially from the gate to the drain, thus the electric field distribution in the drift region of the LDMOS becomes more uniform and flatter without changing the doping concentration of the drift region. As a result, the LDMOS described in embodiments of the present disclosure can increase the breakdown voltage without decreasing the on-resistance. In addition, the number of field plates and the thickness of each region/layer of the LDMOS described in the embodiments of the present disclosure could be flexibly adjusted according to the actual application requirements, thereby further optimizing the electric field distribution in the drift region. Furthermore, just two different masks (e.g., the first mask and the second mask described in the embodiment of FIG. 5) are needed in the present disclosure to form the field plate oxide layers and the field plate barrier layers. Compared to the conventional LDMOS having two-steps field plate structure, no additional mask is needed. Therefore, the step of the field plate structure could be increased without adding the manufacturing cost.

Although the LDMOS of the embodiments of the present disclosure is illustrated and described with the N-channel LDMOS as an example, this is not considered to be a limitation of the present disclosure, and it should be understood by those skilled in the art that the structures and principles given herein are equally applicable to P-channel LDMOS and other types of semiconductor materials and semiconductor devices.

The advantages of the various embodiments of the present disclosure are not confined to those described above. These and other advantages of the various embodiments of the present disclosure will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments. Accordingly, the present invention is not limited except as by the appended claims.

What is claimed is:

1. A lateral double diffused metal oxide semiconductor field effect transistor (LDMOS), comprising:
a semiconductor substrate having a source and a drain;
a gate oxide positioned atop the semiconductor substrate;
a gate positioned between the source and drain;
a first field plate oxide layer and a second field plate oxide layer positioned atop the gate oxide, wherein a spacing is between the first field plate oxide layer and the second field plate oxide layer;
a first field plate barrier layer and a second field plate barrier layer positioned atop the first field plate oxide layer and the second field plate oxide layer, respectively;
a third field plate barrier layer positioned atop the first field plate barrier layer, the second field plate barrier layer, and the spacing between the first field plate oxide layer and the second field plate oxide layer;
a third field plate oxide layer positioned atop the third field plate barrier layer, wherein the third field plate oxide layer comprises a first portion positioned atop the first field plate oxide layer and a second portion positioned atop the spacing between the first field plate oxide layer and the second field plate oxide layer; and
a fourth field plate barrier layer positioned atop the third field plate oxide layer.

2. The LDMOS of claim 1, further comprising:
a dielectric layer positioned atop the third field plate barrier layer and the fourth field plate barrier layer;
a first field plate positioned in the dielectric layer atop the first field plate oxide layer, wherein a lower surface of the first field plate is in contact with the fourth field plate barrier layer;
a second field plate positioned in the dielectric layer atop the spacing between the first field plate oxide layer and the second field plate oxide layer, wherein a lower surface of the second field plate is in contact with the fourth field plate barrier layer; and
a third field plate positioned in the dielectric layer atop the second field plate oxide layer, wherein a lower surface of the third field plate is in contact with the third field plate barrier layer.

3. The LDMOS of claim 1, wherein the spacing between the first field plate oxide layer and the second field plate oxide layer ranges from 0.1 μm to 5.0 μm.

4. The LDMOS of claim 1, wherein the first field plate oxide layer and the second field plate oxide layer have a same thickness.

5. The LDMOS of claim 1, wherein the first field plate oxide layer is twice as thick as the gate oxide.

6. The LDMOS of claim 1, wherein the gate oxide extends laterally from atop the drain to underneath the gate.

7. The LDMOS of claim 1, wherein a thickness of the gate oxide ranges from 200 Å to 500 Å.

8. The LDMOS of claim 1, wherein the semiconductor substrate further comprises:
a body positioned between the source and drain; and
a drift region positioned between the body and the drain.

9. A lateral double diffused metal oxide semiconductor field effect transistor (LDMOS), comprising:
a semiconductor substrate having a source and a drain;
a gate oxide positioned atop the semiconductor substrate;
a gate positioned between the source and drain, wherein the gate comprises a plate portion positioned atop the gate oxide;
a first field plate oxide layer and a second field plate oxide layer positioned atop the gate oxide, wherein a spacing is between the first field plate oxide layer and the second field plate oxide layer;
a first field plate barrier layer and a second field plate barrier layer positioned atop the first field plate oxide layer and the second field plate oxide layer, respectively;
a third field plate barrier layer positioned atop the first field plate barrier layer, the second field plate barrier layer, and the spacing between the first field plate oxide layer and the second field plate oxide layer;
a third field plate oxide layer positioned atop the third field plate barrier layer, wherein the third field plate oxide layer comprises a first portion positioned atop the first field plate oxide layer and a second portion positioned atop the spacing between the first field plate oxide layer and the second field plate oxide layer; and
a fourth field plate barrier layer positioned atop the third field plate oxide layer.

10. The LDMOS of claim 9, further comprising:
a dielectric layer positioned atop the third field plate barrier layer and the fourth field plate barrier layer;
a first field plate positioned in the dielectric layer atop the first field plate oxide layer;
a second field plate positioned in the dielectric layer atop the spacing between the first field plate oxide layer and the second field plate oxide layer; and
a third field plate positioned in the dielectric layer atop the second field plate oxide layer;
wherein a height of a lower surface of the first field plate to a upper surface of the semiconductor substrate is greater than a height of a lower surface of the second field plate to the upper surface of the semiconductor substrate, the height of the lower surface of the second field plate to the upper surface of the semiconductor substrate is greater than a height of a lower surface of the third field plate to the upper surface of the semiconductor substrate, and the height of the lower surface of the third field plate to the upper surface of the semiconductor substrate is greater than a height of the plate portion of the gate to the upper surface of the semiconductor substrate.

11. The LDMOS of claim 10, wherein:
the lower surface of the first field plate is in contact with the fourth field plate barrier layer, the lower surface of the second field plate is in contact with the fourth field plate barrier layer, and the lower surface of the third field plate is in contact with the third field plate barrier layer.

12. The LDMOS of claim 9, wherein the spacing between the first field plate oxide layer and the second field plate oxide layer ranges from 0.1 μm to 5.0 μm.

13. The LDMOS of claim 9, wherein the first field plate barrier layer and the second field plate barrier layer have a same thickness.

14. The LDMOS of claim 9, wherein a thickness of the first field plate barrier layer ranges from 100 Å to 600 Å.

15. A lateral double diffused metal oxide semiconductor field effect transistor (LDMOS), comprising:
a semiconductor substrate having a source and a drain;
an interlayer dielectric layer positioned atop the semiconductor substrate;
a gate conducting layer positioned atop the semiconductor substrate between the source and the drain, wherein the gate conducting layer comprises a plate portion and a channel portion, and a height of the plate portion to a upper surface of the semiconductor substrate is greater than a height of the channel portion to the upper surface of the semiconductor substrate;
a low side field plate barrier layer positioned in the interlayer dielectric layer and comprising a first portion, a second portion and a third portion, wherein the first portion is positioned in the interlayer dielectric layer close to the drain, the second portion is positioned in the interlayer dielectric layer close to the source, and the third portion is positioned between the first portion and the second portion; and
a high side field plate barrier layer positioned in the interlayer dielectric layer atop the first portion and the third portion of the low side field plate barrier layer.

16. The LDMOS of claim 15, further comprising:
a first field plate positioned in the interlayer dielectric layer atop the first portion of the low side field plate barrier layer, wherein a lower surface of the first field plate is in contact with the high side field plate barrier layer;
a second field plate positioned in the interlayer dielectric layer atop the third portion of the low side field plate barrier layer, wherein a lower surface of the second field plate is in contact with the high side field plate barrier layer; and
a third field plate positioned in the interlayer dielectric layer atop the second portion of the low side field plate barrier layer, wherein a lower surface of the third field plate is in contact with the low side field plate barrier layer; wherein
a height of the lower surface of the first field plate to the upper surface of the semiconductor substrate is greater than a height of the lower surface of the second field plate to the upper surface of the semiconductor substrate, the height of the lower surface of the second field plate to the upper surface of the semiconductor substrate is greater than a height of the lower surface of the third field plate to the upper surface of the semiconductor substrate, and the height of the lower surface of the third field plate to the upper surface of the semiconductor substrate is greater than the height of the plate portion of the gate conducting layer to the upper surface of the semiconductor substrate.

17. The LDMOS of claim 15, wherein the interlayer dielectric layer comprises oxide.

18. The LDMOS of claim 15, wherein a width of the third portion of the low side field plate barrier layer ranges from 0.1 μm to 5.0 μm.

19. The LDMOS of claim 15, wherein the low side field plate barrier layer comprises nitride.

20. The LDMOS of claim 15, wherein the low side field plate barrier layer and the high side field plate barrier layer have a same material.
